(19) United States
(12) Patent Application Publication
(10) Pub. No.: US 2012/0106111 A1
(43) Pub. Date: May 3, 2012

(54) ANISOTROPIC ELECTRICALLY AND THERMALLY CONDUCTIVE ADHESIVE WITH MAGNETIC NANO-PARTICLES

(76) Inventors: JOSEPH MAZZOCHETTE, Cherry Hill, NJ (US); Sarwan Kumar Khanna, Carmel, IN (US)

(21) Appl. No.: 12/916,569

(22) Filed: Oct. 31, 2010

(51) Int. Cl. H05K 7/00; H01F 1/00; H01F 1/26; C09K 5/00; H01F 1/04; B82Y 99/00; B82Y 30/00

(52) U.S. Cl. 361/783; 252/71; 252/62.51 R; 252/77; 252/73; 252/62.55; 252/62.54; 977/773; 977/932

(57) ABSTRACT

A composition of matter comprising a plurality of nanoparticles in a non-conductive binder, wherein, the type of nanoparticles form isolated parallel electrically and thermally conductive columns when cured in the presence of the magnetic field. Also wherein the plurality of nanoparticles are Paramagnetic or Ferromagnetic magnetic. Wherein the nano particles are coated, and of a particular shape. Wherein the particles are selected from the group consisting of; Al, Pt, Cr, Mn, crown glass, Fe, Ni, and Co, Ni—Fe/SiO₂, Co/SiO₂, Fe—Co/SiO₂, Fe/nickel-ferrite, Ni—Zn-ferrite/SiO₂, Fe—Ni/polymer, Co/polymer, ferrites, iron oxide and any combination and alloy thereof, and the Binder selected from the group consisting of; epoxies, polyurethanes, polyimides, polymeric materials, silicones, adhesives, acrylates, the UV curable modifier and any combination thereof.

### FIELD OF THE INVENTION

The present invention relates to the art of interconnecting microelectronic packages and components.

### CROSS REFERENCE TO RELATED APPLICATIONS

Not applicable.

### STATEMENT REGARDING FEDERALLY-SPONSORED RESEARCH AND DEVELOPMENT

Not applicable.

### BACKGROUND OF THE TECHNOLOGY

The applications in microelectronic packaging are more and more focused on the fine pitch capability, low-temperature bonding process, electrical, mechanical, and thermal performance. At the wafer level, low yields due to misalignment is today's biggest engineering quest as the interconnection pitch between driver IC and flex or substrate is significantly decreasing.

Anisotropic conductive films and adhesives, hereinafter “ACFs,” are adhesives currently used to provide a mechanical, electrical and thermal connection between electrical components. Anisotropic conductive films consist of conducting particles in an adhesive resin-type polymer film. One of the limitations of ACF materials is that they do not meet the need for fine pitch capability, low-temperature curing and strong adhesion requirements. Furthermore, since most ACF are made of single size metallized particles, connectivity depends on the contact between a few of the round particles and a flat contact pad.

Another issue with today's AFCs, is that pressure needs to applied to sensitive integrated circuits (IC) chips to contact the underlying metallized pads. Thus, the more pressure is asserted on to the chip the greater the connectivity against the pad. The issue with this is that the yields decrease as many of the sensitive IC's are crushed against the substrate.

Another interconnecting technology at the wafer level is flip chip bumping. In order to increase input/output density of IC's, it also means that interconnect densities must also increase apace. This in turn makes it necessary to shorten pitch geometries from around a 30-micron pitch to as narrow as a 10-micron pitch. Today's conventional mounting technologies like gold bumping cannot form such a fine pitch. Manufacturers are having to resort to multiple rows of bumps at higher pitches as a costly solution, and again low yield becomes an issue.

Bumping the IC given that an effective electrical connection is predicated on a certain area of bump material being in contact with the particular conductive film creates conductivity and bonding issues. Reliability decreases if the width of the bump is reduced to accommodate a finer pitch. Decreasing the gap between adjoining bumps is no answer either, for that can cause new problems such as short-circuiting.

After bumping, alignment is also a big concern for surface mount and flip chips. Pads and bumps are never precisely aligned, and the difference between the artwork and the actual pads, can vary significantly. Lot-to-lot variations are also a major yield issue. Furthermore, misaligned ICs create cracks, connectivity, and related reliability issues.

There is nothing in today's marketplace that incorporates fine pitch capability, a low-temperature bonding process, with high electrical, mechanical, and thermal performance. Furthermore, there is a need in the microelectronic arts to interconnect an IC with a substrate, or heat sink, without the use of pressure. Moreover, in the ACF industry, it would be desirable to progress from mechanically connecting large static conductive particles, to a pressure-less higher conductivity connection without sacrificing high yields.

### BRIEF DESCRIPTION OF THE SEVERAL VIEWS OF THE DRAWINGS

The foregoing summary, as well as the following detailed description of the technology, will be better understood when read in conjunction with the appended drawings. For illustrating the technology, the figures are shown in the embodiments that are presently preferred. It should be understood, however, that the technology is not limited to the precise arrangements and instrumentalities shown. In the drawings:

FIG. 1 depicts at least one embodiment of the technology in 3D, where an electronic package uses Magnetic Anisotropic Conductive Adhesive with nano particles to create thermal and electrical interconnections.

FIG. 2 depicts at least one cross-section embodiment of the technology, where an electronic package uses Magnetic Anisotropic Conductive Adhesive with nano particles to create thermal and electrical columns.

FIG. 3 depicts at least one close up embodiment of the technology, where it is depicted how nano particles align to create thermal and electrical high pitch columns under a magnetic field.

FIG. 4 depicts at least one embodiment of the technology in 3D, where an electronic package uses Magnetic Anisotropic Conductive Adhesive with nano particles to create thermal and electrical interconnections between two sandwiched IC's and two circuit boards.

FIG. 5 depicts at least one cross-section embodiment of the technology, where an electronic package uses Magnetic Anisotropic Conductive Adhesive with nano particles to create thermal and electrical high pitch columns interconnects.

FIG. 6 depicts at least one close up embodiment of the technology, where it is depicted how nano particles align to create thermal and electrical high pitch columns.

FIG. 7 depicts at least one close up embodiment of the technology, where it is depicted how nano particles align to create better particle packed columns.

FIG. 8 depicts at least one close up embodiment of the technology, where it is depicted how nano particles are coated in a round shape.

FIG. 9 depicts at least one close up embodiment of the technology, where it is depicted how nano particles look.

FIG. 10 depicts at least one close up embodiment of the technology, where it is depicted how nano particles are coated in an oval shape.

FIG. 11 depicts at least one close up embodiment of the technology, where it is depicted how nano particles are coated in a flake type uneven shape.

FIG. 12 depicts at least one cross-section embodiment of the technology, where an electronic package uses Magnetic Anisotropic Conductive Adhesive with nano particles before the magnetic field is applied.

FIG. 13 depicts at least one close up embodiment of the technology, where it is depicted how nano particles behave before a magnetic field is applied.

FIG. 14 depicts at least one close up embodiment of the technology, where it is depicted how nano particles behave after 5 seconds in a magnetic field.

FIG. 15 depicts at least one close up embodiment of the technology, where it is depicted how nano particles behave after 10 seconds in a magnetic field.

FIG. 16 depicts at least one close up embodiment of the technology, where it is depicted how nano particle columns appear in its completed stable form.

FIG. 17 depicts at least one cross-section embodiment of the technology, where an electronic package uses Magnetic Anisotropic Conductive Adhesive with nano particles after the magnetic field is applied.

FIG. 18 depicts at least one top-view cross-section embodiment of the technology, where it is depicted how nano particle columns appear in its completed stable form after the curing in a magnetic field.

### DESCRIPTION OF THE TECHNOLOGY

The present technology depicts an inventive solution to the fore mentioned issues related to anisotropic conductive films and adhesives.

Unless otherwise defined, all terms of art, notations and other scientific terms or terminology used herein are intended to have the meanings commonly understood by those of skill in the art to which this invention pertains. In some cases, terms with commonly understood meanings are defined herein for clarity and/or for ready reference, and the inclusion of such definitions herein should not necessarily be construed to represent a substantial difference over what is generally understood in the art. Many of the techniques and procedures described, or referenced herein, are well understood and commonly employed using conventional methodology by those skilled in the art. As appropriate, procedures involving the use of commercially available kits and reagents are generally carried out in accordance with manufacturer defined protocols and/or parameters, unless otherwise noted.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, or should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as only one of or “exactly one of,” or, when used in the claims, “consisting of,” will refer to the inclusion of exactly one element of a number or list of elements. In general, the term or as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

“Magnetic nanoparticles” as used herein, and in the claims, shall be interpreted as a class of nanoparticle which can be manipulated using magnetic field. Such particles commonly comprise; Paramagnetic elements such as, Al, Pt, Cr, manganese, crown glass, and Ferromagnetic such as; iron, nickel, and cobalt and a number of their alloys. Furthermore, “nanoparticles” as use herein shall be interpreted as magnetic particles with sizes from a few nanometers up to micrometers. Typically the particles range from 1 nano meter to 10 micron meters in size, and may display superparamagnetism, a size at which materials display different properties to the bulk material. As used herein in the specification and in the claims, there is no strict dividing line between “nanoparticles” and “non-nanoparticles,” material dependent particles are hereby and in the claims also interpreted as particles with much larger in size than 10 micron meters.

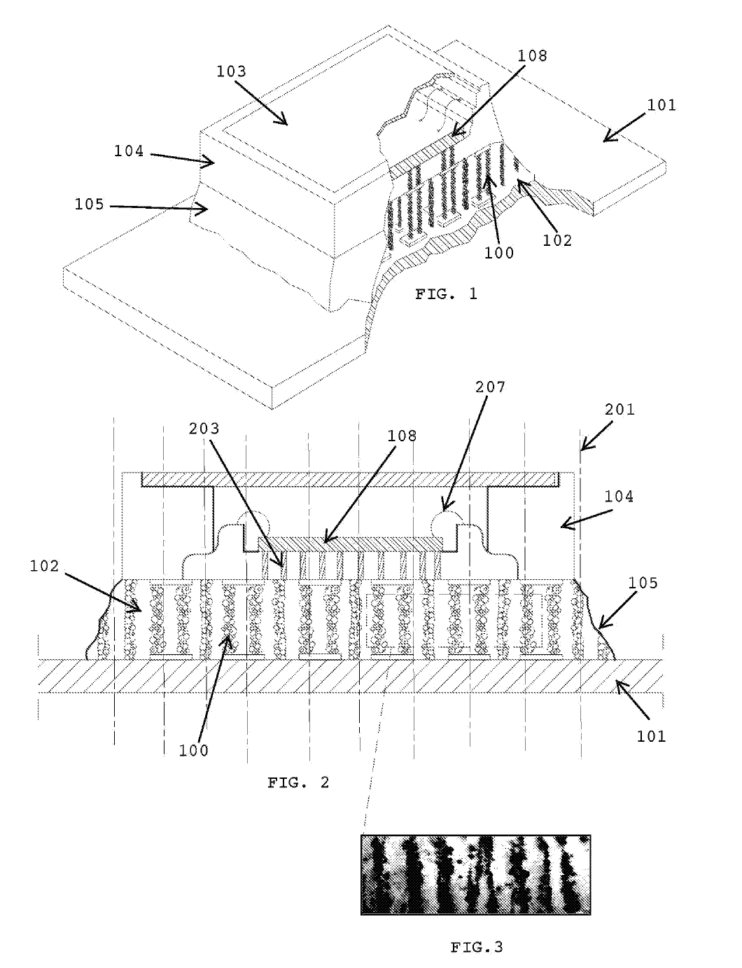

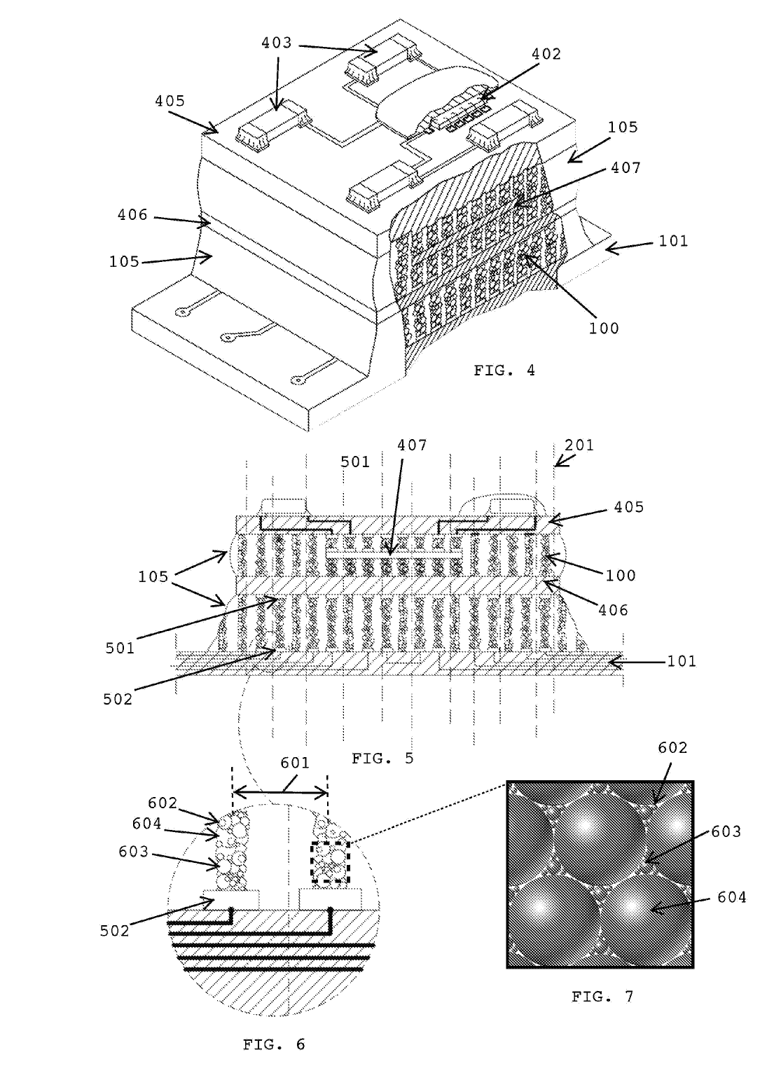

Magnetic Anisotropic Conductive Adhesive 105, hereinafter “MACA”, first developed by one of the afore-captioned inventors, is a low temperature, lead free interconnect for flip chip and 3D packaging as seen in FIG. 1 and FIG. 4. The MACA 105 is applied as a paste without any pressure and then cured either with heat at low temperature or with Ultra Violet (UV) in a magnetic field 201.

MACA technology enables low cost flip chip assembly by eliminating steps such as patterning of the adhesive, under bump metallization, bumping and flip chip bonding. For 3D packaging such as in FIG. 1 and FIG. 4, MACA 105 offers numerous benefits such as thin form factor, low assembly cost, and low parasitic impedances. The non-application of pressure and low temperature assembly is also ideal for interconnect formation in organic photo-voltaics, OLEDs and in other low temperature packaging applications.

The technology described herein may be used in conjunction, and is not limited to the following electronic packages: ball-grid array type packages mounted on substrate, semiconductor integrated circuit and corresponding package such as dual-in-line (DIP), SMT DIP, BGA, chip-scale package, semiconductor integrated circuit mounted directly on a circuit board (flip-chip) and a semiconductor integrated circuit mounted on one or more integrated circuits of the same or different dimensions, multiple stacked integrated circuits, flat panel display modules for high-resolution, out lead bonding (OLB), flex to printed circuit board bonding (PCB), chip-on-glass (COG), and chip-on-film (COF).

FIG. 1 and FIG. 4 shows a 3D depiction of land grid arrays (LGAs). FIG. 1, shows a simple MACA 105 construction consisting of a single LGA mounted on a printed circuit board 101. FIG. 2 depicts a cross-section the LGA, where the IC 108 is inside the package 104 enclosed with a lid 103. Here, thermal vias 203 conduct heat away from the IC source. The heat travels into the particle columns 100 and into the board 101. Electrical signals travel to and from the IC through the wire-bonds 207, through the columns 100 into the PCB.

FIG. 5 depicts a cross-section of a LGA, comprising of a multi-structure electronic packaging using MACA 105 technology. Within this structure, a flip chip 407 was assembled using MACA 105. The MACA 105, provides for a lead-free processing as well as cost-effective packaging method. The 3D structure of FIG. 4, comprise surface mount components 403 including an SMT IC 402 bonded to the circuit board 405. Under the circuit board 405 electrical pads connect to the eimbedded Flip Chip IC 407 and on the back of the larger 406 IC also serving as thermal connections. All of the interconnections are made using MACA 105 and magnetic nano-particle stacked 100. The large IC 406 Flip Chip, was connected using the same MACA 105 to the large PCB substrate 101 as seen in FIG. 6.

A person skilled in the art may use other types of microelectronic packages or a combination thereof for the same purpose or to achieve similar result. For example, any individual semiconductor device such as an LED die, transistor, diode, or other device mounted in any of the aforementioned constructions. The connection of an electrical assembly such as an LCD, plasma, OLED, LED, or other display and connecting substrate, such as, printed circuit board or ceramic substrates. MACA 105 solves all the aforementioned issues and provides for high mechanical reliability, good electrical performance at high-frequency range and effective thermal conductivity for high current density.

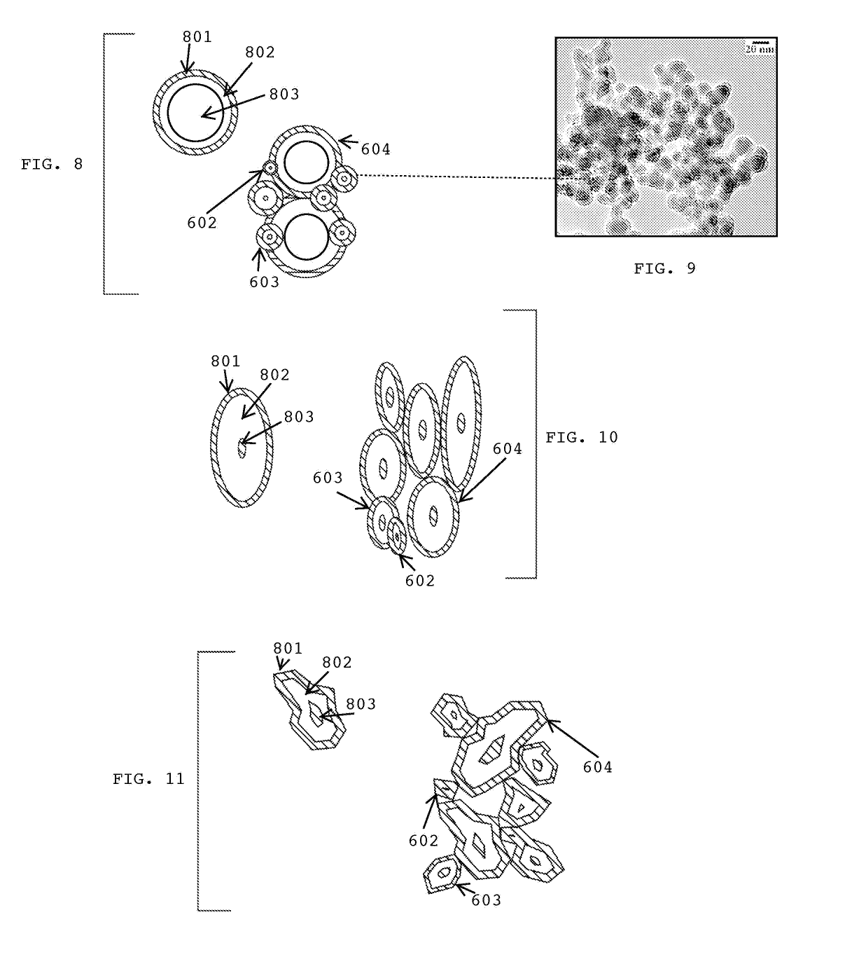

In at least one embodiment of the technology, the MACA 105 material comprise at least one adhesive binder 102 such as an, epoxy, epoxies, polyurethanes, polyimides, polymeric materials, silicone, adhesive, (any combination thereof), and at least one conductive filler FIG. 7, FIG. 9. The filler is made up of particles 602, 603, 604 with magnetic properties which are exploited to create a thermally and electrically conductive path in one direction as seen in FIG. 3.

The path of the conductivity is formed using an external magnetic field 201 which causes the particles 602, 603, 604 to orient in regular columns FIG. 3. Once the columns are formed, the adhesive 102 may be cured. The cured adhesive 102 holds the columns FIG. 6 in place after the magnetic field 201 is withdrawn. The adhesive binder 102 will shrink as it cures which improves the electrical and thermal conductivity. This technology herein an advanced improvement and the solution to the aforementioned issues with today's ACFs.

The technology described herein involves at least one type of filler particle used as the filler material as seen in FIG. 8, FIG. 10, FIG. 11. After experimentation and research, the above captioned inventors found that the use of a smaller particle size improves the electrical and thermal conductivity of the columns 100 and decreases the column diameter and the spacing between columns 601. In at least one embodiment of the present technology, the filler material consists of sub-micron particles also known as nanoparticles and magnetic nanoparticles.

In at least one embodiment of the technology, the MACA 105 material may contain at least one magnetic nano-particle of the type disclosed in FIG. 9, where the particle size is less or equal to 0.1 microns. In the presence of a magnetic field 201 the nano-particles 602, 603, 604 will form regular columns 100 which will provide the electrical and thermal connections as seen in FIG. 3. The columns 100 will be held permanently in place without the magnetic field after the polymer binder matrix 102 is cured. The polymer binder matrix 102 may be cured by UV radiation, heat and room temperature. A person skilled in the art may use other types of curing or a combination thereof for the same purpose or to achieve similar result.

As seen in FIG. 6, unwanted connections between pads are avoided by controlling the column diameter and pitch 601. Multiple column connections are created as in FIG. 5, and at each pad location reduce the contact resistance and accommodate IC-Pad 501 to PCB-Pad 502 misalignment. The technology herein increases yields significantly just by avoiding the painstaking misalignment issues of other bonding technologies. The MACA 105 forms columns 100 of conductive material at a regular interval. The pitch and diameter of the columns are determined by the magnetic field, volume fraction of the particles, particle size, and particle shape.

In another embodiment of the invention, different sized particles are used in combination to achieve a better packing structure of columns 100, and FIG. 6. For example in FIG. 7, coarse particles 604 leave a substantial free void volume, adding the need of smaller particles 603 to fill them. That, however, leaves even smaller voids, therefore using nanoparticles 602 to fill those. A person skilled in the art may use several sizes or a combination thereof for the same purpose or to achieve similar result. Even if the particles are not perfect spheres such as in FIG. 10, and not uniformly sized or consist of more than just three distinct particle sizes, if properly mixed within the binder matrix 102, the packing will substantially improve and become uniform throughout the column 100.

FIGS. 8-11, depicts a three-particle-size example. By increasing the packing density of the columns 100, the use of magnetic nano-particles is useful because the small particles improve thermal and electrical conductivity, and reduce the column pitch 601. As a result of its small size, the particles exhibit greater permeability and consequently improve the integrity of the conductive column structure and surface regularity. Surface regularity is especially important in high frequency packages.

A person skilled in the art may use other types of Paramagnetic, Ferromagnetic particles or a combination thereof for the same purpose or to achieve similar result. Examples of nano-material particles include Al, Pt, Cr, manganese, crown glass, MgO₂, and Ferromagnetic such as; iron, nickel, and cobalt, alloys such as Ni—Fe/SiO₂, Co/SiO₂, Fe—Co/SiO₂, Fe/nickel-ferrite, Ni—Zn-ferrite/SiO₂, Fe—Ni/polymer, and Co/polymer magnetic nano-composites, ferrites, and iron oxide.

Nanoparticles as seen in FIG. 9 are made directly as dry powders and they will rapidly aggregate through a solid bridging mechanism in as little as a few seconds. To keep them separate, they must be prepared and stored in a liquid dispersant designed to facilitate sufficient inter-particle repulsion forces to prevent aggregation until mixed with the polymer matrix binder. The physical and chemical properties of magnetic nanoparticles largely depend on the synthesis method and chemical structure.

A first preferred embodiment includes between 10-40 wt % of 3 micron iron particles coated with silver in a polymer binder. The polymer binder is formed from reaction product of between 82% and 91% by weight of a compound and no more than about 6% by weight of a catalyst. The compound includes about 85% by weight of urethane and epoxy acrylates such as those available from Cytec Industries Inc, about 5% by weight of a vinyl monomer such as those available from International Specialty Polymer, and no more than 10% by weight of a UV curable modifier such as the IRGACURE PhotoInitiators available from Ciba Specialty Chemicals. The MACA 105 was applied as a paste dispensed on a coating thickness 100 μm on a ceramic substrate 101 without any pressure and then cured with UV light in a magnetic field 201 of 2000 gauss. This resulted in the self-assembly of conductive columns 100 at regular intervals FIG. 3 throughout the MACA 105 thickness (Z-Axis). The columns create electrical and thermal interconnection in the Z-Axis, while maintaining electrical insulation in the X-Y plane.

A second preferred embodiment includes between 10-40 wt % of 3 micron iron particles coated with silver in a polymer binder. The polymer binder is formed from reaction product of between 82% and 91% by weight of a compound and no more than about 6% by weight of a catalyst. The compound includes about one-third by weight of each of an aromatic epoxy resin, a dimer fatty acid diglycidyl ester and an oxirane. Suitable aromatic epoxy resins include, but are not limited to diglycidyl ethers of bisphenol-A and bisphenol-F and other such resins, such as EPON resins available from Hexion Specialty Chemicals. Solvent Dibasic Ester-1 was used to target a viscosity of 53,000 cP. The MACA 105 was screen printed using a 325 WPI Stainless Steel Mesh, 1.5 mil diameter wire, 0.5 mil emulsion for a coating thickness 100 μm on a PWB substrate 101. It was then heat cured at 60 min at 70° C. or at 1-2 min at 150° C. in a magnetic field 201 of 2500 gauss. This resulted in the self-assembly of conductive columns 100 at regular intervals FIG. 3 throughout the MACA 105 thickness (Z-Axis). The columns create electrical and thermal interconnection in the Z-Axis, while maintaining electrical insulation in the X-Y plane.

A third preferred embodiment includes between 10-20 wt % of 10 nanometer iron particles coated with silver and 10-20 wt % of 100 nanometer iron particles coated with silver in a polymer binder. The polymer binder is formed from reaction product of between 82% and 91% by weight of a compound and no more than about 6% by weight of a catalyst. The compound includes about one-third by weight of each of an aromatic epoxy resin, a dimer fatty acid diglycidyl ester and an oxirane. Suitable aromatic epoxy resins include, but are not limited to diglycidyl ethers of bisphenol-A and bisphenol-F and other such resins, such as EPON resins available from Hexion Specialty Chemicals. Solvent Dibasic Ester-1 was used to target a viscosity of 53,000 cP. The MACA 105 was screen printed using a 325 WPI Stainless Steel Mesh, 1.5 mil diameter wire, 0.5 mil emulsion for a coating thickness 100 μm on a PWB substrate 101. It was then heat cured at 60 min at 70° C. or 1-2 min at 150° C. in a magnetic field 201 of 2500 gauss. This resulted in the self-assembly of conductive columns 100 at regular intervals FIG. 3 throughout the MACA 105 thickness (Z-Axis). The columns create electrical and thermal interconnection in the Z-Axis, while maintaining electrical insulation in the X-Y plane.

The typical properties of cured MACA 105 are:

| Property | Specification | |
|---|---|---|
| Glass transition temperature | 130° | C. |
| Coefficient of thermal | 65 | ppm/° C. |
| expansion (CTE) below Tg | | |
| Shrinkage | <5% | |
| Thermal conductivity | >4.5 | W/mK |
| Volume resistivity in Z-Axis | 7 | mΩcm |
| Volume resistivity in X-Y | >10¹¹ | Ωcm |
| Elastic modulus (ISO 527- 2) | 500 | N/mm² |

| | |
|---|---|
| Operating temperature | Max. 100° C. |
| Breaking stress under shear | 6.8 × 10⁶ N/m² Lap shear test on aluminum |

In another embodiment of the technology, the inventors herein, proved that the electrical and thermal conductivity of the MACA 105 may be improved by coating 801 the particles with a conductive material such as silver, gold, copper, or nickel. Multi-layered particles such as double 801, 802 and triple-layered particles were developed to prevent silver migration and/or prevent surface oxidation. The core 803, was made of Paramagnetic, Ferromagnetic materials, thus creating the bulk driving magnetic force of the particles.

A person skilled in the art may use other types of magnetic nanoparticle shapes or a combination thereof for the same purpose or to achieve similar result. Typical particles claimed herein are spherical FIG. 8, oval FIG. 10, flake FIG. 11, tubular, pill-shaped, box shaped, or any combination thereof. Having a mixture of particles improves the thermal and electrical conductivity and reduces the pitch 601 and diameter of the columns as seen in FIG. 6. No matter what the shape is, after formation, the columns maintain their structure due to immobilization within a now rigid binder polymer matrix.

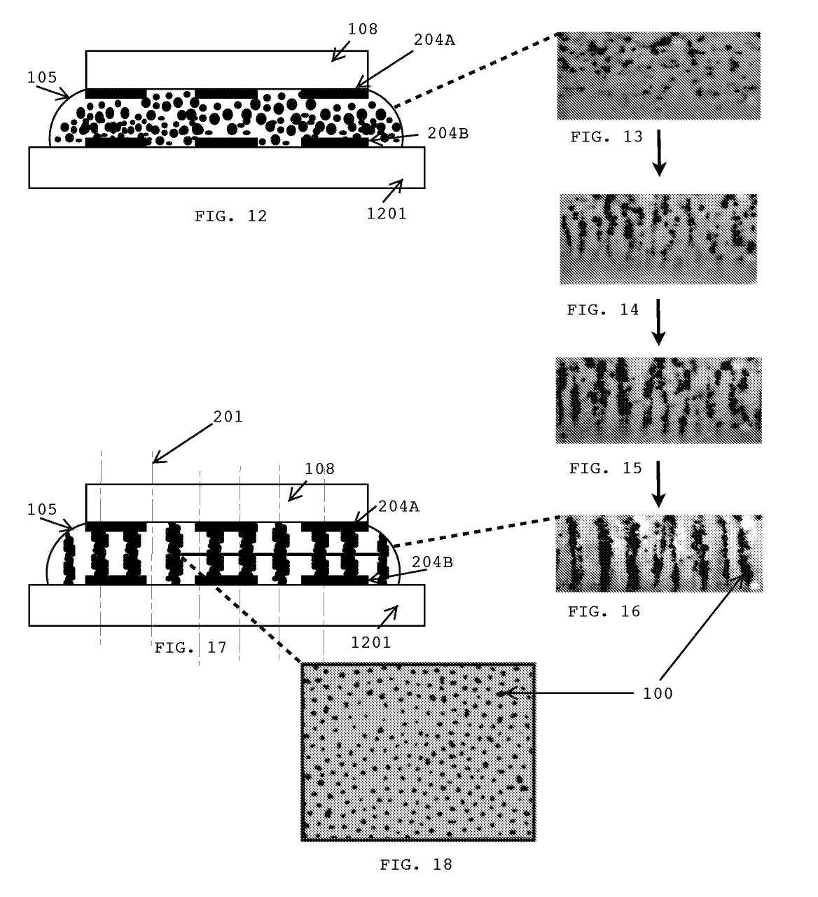

FIGS. 12-18 depict the formation of the magnetic particle columns 100 in the above mentioned MACA 105 mixtures. In FIG. 12, the IC 108 is placed in top of a glob of MACA 105 material on to a PCB or heatsink 1201. Notice that pads 204A and 204B do not have to be perfectly aligned. FIG. 13 depicts randomly dispersed particles before cure. FIG. 14 after two seconds, it depicts particle alignment begins when applying a 400-2500 Gauss magnetic field. FIG. 14, after 5 seconds, it depicts column settling. FIG. 15, finally after 10 seconds, the columns 100 appear in its completed stable form. FIG. 16 is a top view cross-section of the MACA 105 depicting the diameter of the columns 100 after the curing.

It will be appreciated by those skilled in the art that changes could be made to the embodiments described above without departing from the broad inventive concept thereof. It is understood, therefore, that this technology is not limited to the particular embodiments disclosed, but it is intended to cover modifications within the spirit and scope of the present technology.

What is claimed is:

1. A composition of matter comprising:
at least one type of a plurality of nanoparticles; and
at least one type of a non-conductive binder, said at least one type of a plurality of nanoparticles suspended in said at least one type of a non-conductive binder;
wherein, said at least one type of a plurality of nanoparticles form isolated parallel electrically and thermally conductive columns when cured in the presence of at least one magnetic field.

2. The composition of matter of claim 1, wherein the at least one type of a plurality of nanoparticles are Paramagnetic or Ferromagnetic magnetic nanoparticles.

3. The composition of matter of claim 1, wherein the at least one type of a plurality of nanoparticles are further comprised of at least one coating.

4. The composition of matter of claim 3, wherein the at least one coating is selected from the group consisting of; such as silver, gold, copper, nickel, and any combination and alloy thereof.

5. The composition of matter of claim 1, wherein the at least one type of a plurality of nanoparticles further comprise at least one shape.

6. The composition of matter of claim 5, wherein the at least one type of a plurality of nanoparticles shape is selected from the group consisting of; spherical, oval, flake, tubular, pill-shaped, box shaped, and any combination thereof.

7. The composition of matter of claim 2, wherein the at least one type of a plurality of nanoparticles are selected from the group consisting of; Al, Pt, Cr, Mn, crown glass, Fe, Ni, and Co, Ni—Fe/SiO₂, Co/SiO₂, Fe—Co/SiO₂, Fe/nickel-ferrite, Ni—Zn-ferrite/SiO₂, Fe—Ni/polymer, Co/polymer, ferrites, iron oxide and any combination and alloy thereof.

8. The composition of matter of claim 1, wherein the at least one type of a non-conductive binder is selected from the group consisting of; acrylates, epoxies, polyurethanes, polyimides, polymeric materials, silicones, adhesives, and any combination thereof.

9. The composition of matter of claim 8, wherein said non-conductive binder further comprises at least one UV curable modifier.

10. A magnetic anisotropic conductive adhesive comprising:
at least one type of a plurality of Paramagnetic or Ferromagnetic nanoparticles with at least one coating;
at least one type of a plurality of Paramagnetic or Ferromagnetic non-nanoparticles with at least one coating; and
at least one type of a non-conductive binder, said at least one type of a plurality of nanoparticles, and said at least one type of a plurality of non-nanoparticles are suspended in said at least one type of a non-conductive binder;
wherein, said at least one type of a plurality of nanoparticles and said at least one type of a plurality of non-nanoparticles form isolated parallel electrically and thermally conductive columns when cured in the presence of at least one magnetic field.

11. The magnetic anisotropic conductive adhesive of claim 10, wherein the at least one coating is selected from the group consisting of; such as silver, gold, copper, nickel, and any combination and alloy thereof.

12. The magnetic anisotropic conductive adhesive of claim 10, wherein the at least one type of a plurality of Paramagnetic or Ferromagnetic nanoparticles with at least one coating, and at least one type of a plurality of Paramagnetic or Ferromagnetic non-nanoparticles with at least one coating, further comprise at least one shape.

13. The magnetic anisotropic conductive adhesive of claim 12, wherein the at least one shape is selected from the group consisting of; spherical, oval, flake, tubular, pill-shaped, box shaped, and any combination thereof.

14. The magnetic anisotropic conductive adhesive of claim 10, wherein the at least one type of a plurality of Paramagnetic or Ferromagnetic nanoparticles with at least one coating, and at least one type of a plurality of Paramagnetic or Ferromagnetic non-nanoparticles with at least one coating, are selected from the group consisting of; Al, Pt, Cr, Mn, crown glass, Fe, Ni, and Co, Ni—Fe/SiO₂, Co/SiO₂, Fe—Co/SiO₂, Fe/nickel-ferrite, Ni—Zn-ferrite/SiO₂, Fe—Ni/polymer, Co/polymer, ferrites, iron oxide and any combination and alloy thereof.

15. The magnetic anisotropic conductive adhesive of claim 10, wherein the at least one type of a non-conductive binder is selected from the group consisting of; acrylates, epoxies, polyurethanes, polyimides, polymeric materials, silicones, adhesives, and any combination thereof.

16. The composition of matter of claim 15, wherein said non-conductive binder further comprises at least one UV curable modifier.

17. An electronic package comprising:
at least one integrated circuit chip;
at least one printed circuit board; and
at least one magnetic anisotropic conductive adhesive, said at least one magnetic anisotropic conductive adhesive further comprising at least one type of a plurality of nanoparticles and at least one type of a non-conductive binder, said at least one type of a non-conductive binder suspend said at least one type of a plurality of nanoparticles;
wherein, said at least one type of a plurality of nanoparticles form isolated parallel electrically and thermally conductive columns from at least one integrated circuit chip to at least one printed circuit board when cured in the presence of at least one magnetic field.

18. The electronic package of claim 17, wherein at least one type of a plurality of nanoparticles is coated with materials selected from the group consisting of; such as silver, gold, copper, nickel, and any combination and alloy thereof.

19. The electronic package of claim 17, wherein the at least one type of a plurality of nanoparticles are selected from the group consisting of; Al, Pt, Cr, Mn, crown glass, Fe, Ni, and Co, Ni—Fe/SiO₂, Co/SiO₂, Fe—Co/SiO₂, Fe/nickel-ferrite, Ni—Zn-ferrite/SiO₂, Fe—Ni/polymer, Co/polymer, ferrites, iron oxide and any combination and alloy thereof.

20. The electronic package of claim 17, wherein at least one type of a non-conductive binder is selected from the group consisting of; epoxies, polyurethanes, polyimides, polymeric materials, silicones, adhesives, acrylates, at least one UV curable modifier and any combination thereof.
